(19) United States
(12) Patent Application Publication
(10) Pub. No.: US 2011/0078498 A1
(43) Pub. Date: Mar. 31, 2011

(54) RADIATION-HARDENED HYBRID PROCESSOR

(75) Inventor: Thomas P. Flatley, Huntingtown, MD (US)

(73) Assignee: United States of America as represented by the Administrator of the National Aeronautics and Spac, Washington, DC (US)

(21) Appl. No.: 12/570,134

(22) Filed: Sep. 30, 2009

(51) Int. Cl. G06F 11/07; G06F 11/10; H03M 13/09

(52) U.S. Cl. 714/15; 714/807; 714/E11.023; 714/E11.032

(57) ABSTRACT

A method of providing radiation hardening for a modular computational component having a first memory and a second memory and being connectable to an external platform comprises providing a radiation tolerant field programmable gate array having a pair of processors, processing data from the external platform according to instructions stored in the first memory, and executing instructions stored in the second memory to provide radiation hardening by software. The instructions comprise instructions to execute identical processing operations for the data of the external platform in each of the pair of processors, instructions to identify a data corruption indicia for each of the identical processing operations, instructions to compare the identified data corruption indicia, and instructions to repeat the identical processing operations if the data corruption indicia show corrupted data.

### ORIGIN OF THE INVENTION

The invention described herein was made by an employee of the United States Government, and may be manufactured and used by or for the Government for governmental purposes without the payment of any royalties thereon or therefor.

### FIELD

The present teachings relate to modular computational components and providing radiation hardening by design and software therefore, wherein processors provided in a radiation tolerant FPGA can be utilized to provide increased processing power with reliability close to that of a radiation-hardened processor.

### BACKGROUND

Modern electronic devices utilize computational components to carry out various functions that are necessary to or that enhance the device's functionality. The computational components can be in the form of circuit boards, wired-in processors, or other fixed or removable elements containing components that carry out computations, data processing, and other functions.

In some cases, these devices can be designed to operate in hostile environments, meaning environments that can negatively affect the functioning of the devices. For example, these environments can include radiation or other conditions that are known to negatively affect the performance of the devices. It is thus useful to provide radiation-hardening to the computational components, to prevent and/or mitigate data errors and computational component failures due to radiation and other effects.

Three levels of processor or component radiation tolerance are known to exist. The first level is an unprotected component, which can experience both recoverable errors (e.g., bit flips) and destructive errors when utilized in a hostile environment. The second level is commonly referred to as radiation tolerant, and is designed such that destructive errors are avoided in hostile environments, but recoverable errors such as bit flips may still occur. The third level is commonly referred to as radiation hardened, and experiences neither recoverable nor destructive errors when utilized in a hostile environment. The processing power of radiation hardened processors tends to be less than commercially-available non-radiation-hardened processors. The processing power of a radiation-hardened processor can be, for example, one or two generations behind commercially-available non-radiation-hardened processors.

It is beneficial to use computational components that can easily be added to existing or to new platforms, without having to custom design the computational components. In particular, it is useful to provide standard interfaces and communication protocols to the computational components, so that one or more computational components can be easily added to a standard platform, as needed, to increase the computing power of the platform.

### SUMMARY

Embodiments of the present teachings disclosed herein provide a modular computational component, such as a radiation-tolerant FPGA, that can be added to an existing platform to increase its computational performance without the need to design and test a customized processor. An in-flight reprogrammable and/or reconfigurable logic structure can provide the ability to change the operation of the modular computational component after assembly of the modular computational component in a platform, and/or after deployment of the platform.

The modular computational component according to the present teachings can include one or more radiation tolerant components that are monitored by a radiation hardened microprocessor, so that they can operate in a radioactive environment with minimal errors in data being processed. For example, in accordance with various embodiments of the present teachings, radiation hardening by design can be obtained by having radiation tolerant reconfigurable processors process data concurrently and compare their output to identify possible errors (inconsistent data), and additionally having a radiation hardened processor oversee the operation and error-checking of the radiation tolerant processors, resulting in mitigation of most upsets.

In addition, in accordance with certain embodiments, a radiation hardening by software scheme can be employed to mitigate the majority of the remaining upsets. In the context of the present teachings, radiation hardening by software refers to the use of functions or software applications that are executed to identify radiation-induced errors occurring in the radiation tolerant processors, and to take an appropriate corrective action.

Modular computational components are increasingly included in different devices, from scientific instrument platforms to consumer products, to perform various functions that enhance the devices' utility. These modular computational components can control operation of the device or platform of which they are a part, can carry out data processing and manipulation, and/or can control communication with a remote station. The addition of computing power to a device can be simplified by using one or more standardized modular computational components, which can be added as desired to various different platforms by using standard connections and protocols.

For example, such modular computational components can be added or removed from electronic devices as necessary to provide a desired level of computing performance. In the context of the present teachings, a modular computational component is intended to comprise an element that can be added and removed from a device to provide functionality, for example, computing power, without the need to customize the element. The modular computational component also provides the ability to easily exchange parts thereof, such as replacing an older CPU with a newer model, without having to redesign the modular computational component.

In some applications, the modular computational components must be able to withstand hostile environmental conditions. For example, radiation can have serious negative effects on CPUs, memory components, and other electronic parts that are typically included in the modular computational component according to the present teachings. Bombardment by neutrons, gamma rays, alpha particles, and other particles and electromagnetic waves can cause damage (i.e., destructive errors) to the modular computational component or transient errors (e.g., bit flips) in CPUs and memory elements. Devices designed for use in space are particularly subject to damage and errors from radiation, due to the strong radiation fields present outside the Earth's atmosphere. In addition, many other sensor platforms, instruments, and other devices can be subject to similar damage from natural or man-made radiation.

In accordance with various embodiments of the present teachings, several approaches can be taken to effectively radiation harden a modular computational component to be used in radioactive or other hostile environments. In this context, radiation is meant to include both electromagnetic waves such as X-rays, gamma rays etc., and particles such as neutrons, electrons, alpha particles and other that can cause damage to computing elements by ionization or other mechanisms. Current processors are subject to various errors from radiation, such as bit flip errors and destructive errors. Bit flip errors are a form of single-event upsets in which a state change occurs in memory or in a register, such as from 0 to 1 or vice versa. These are generally not fatal to the device, but can require correction to avoid propagation of errors in computations based thereon. Critical upsets are more serious errors, and generally require a shutdown and restart, or a reset of the computing device affected. Certain embodiments of radiation hardening by design according to the present teachings can address single-event upsets, destructive errors, and other errors that can result from radiation exposure.

Methods for radiation hardening fall in one of two types. First, physical radiation hardening methods can include using shielding to protect certain elements of the modular computational component from radiation, and selecting materials that are less susceptible to damage and effects from radiation. Second, logical hardening methods can use software commands to detect and repair corrupt data, or to reset the affected electronic component in case of serious radiation errors. The logical hardening methods can include error correcting methods for replacing corrupted data with data stored in memory, watchdog circuits, checksums, and other techniques. Redundant electronic components can also be used to counter damage and errors due to radiation. Multiple processors, for example, can be used to conduct identical computations, and a comparator or arbiter device can be used for comparing the results to determine whether one of the processors is defective. In a typical conventional configuration, three processors can be necessary to discover an error and to identify the defective processor.

The present teachings provide a modular computational component connectable to an external platform. The modular computational component comprises: an input/output portion having at least one connection for receiving an input signal to be processed, and at least one connection for sending a processed output signal to the external platform; a radiation tolerant first field programmable gate array having a pair of processors configured to process the input signal; a first memory configured to contain reconfigurable instructions for the pair of processors that, when the reconfigurable instructions are executed, process the input signal and obtain the output signal; a second memory containing instructions that, when executed, provide radiation hardening by software for at least the pair of processors, by identifying radiation-induced errors and taking corrective action; and a reset logic element configured to selectively reset at least one of the first field programmable gate array and at least one of the pair of processors in response to a reset command.

The present teachings also provide a method of providing radiation hardening for a modular computational component having a first memory and a second memory and being connectable to an external platform. The method comprises providing a radiation tolerant field programmable gate array having a pair of processors, processing data from the external platform according to instructions stored in the first memory, and executing instructions stored in the second memory to provide radiation hardening by software. The instructions comprise instructions to execute identical processing operations for the data of the external platform in each of the pair of processors, instructions to identify a data corruption indicia for each of the identical processing operations, instructions to compare the identified data corruption indicia, and instructions to repeat the identical processing operations if the data corruption indicia show corrupted data.

The present teachings further provide a modular computational component connectable to an external platform and comprising: an input/output portion having at least one connection for receiving an input signal to be processed, and at least one connection for sending a processed output signal to the external platform; a radiation tolerant field programmable gate array having a pair of processors configured to process the input signal; a first memory configured to contain reconfigurable instructions for the pair of processors that, when the reconfigurable instructions are executed, process the input signal and obtain the output signal; a second memory containing instructions that, when executed, provide radiation hardening by software for at least the pair of processors, by identifying radiation-induced errors and taking corrective action; a radiation hardened microprocessor configured to check output from the field programmable gate array for radiation-induced errors and take corrective action; and a reset logic element configured to selectively reset at least one of the first field programmable gate array and at least one of the pair of processors in response to a reset command.

Additional objects and advantages of the present teachings will be set forth in part in the description which follows, and in part will be obvious from the description, or may be learned by practice of the teachings. The objects and advantages of the present teachings will be realized and attained by means of the elements and combinations particularly pointed out in the appended claims.

It is to be understood that both the foregoing general description and the following detailed description are exemplary and explanatory only and are not restrictive of the present teachings, as claimed.

The accompanying drawings, which are incorporated in and constitute a part of this specification, illustrate embodiments of the present teachings and, together with the description, serve to explain the principles of the present teachings.

### BRIEF DESCRIPTION OF THE DRAWINGS

Exemplary embodiments of the present teachings are described below with reference to the appended drawings, in which:

FIG. 1 is a diagram showing functional blocks of a modular computational component according to an embodiment of the present teachings;

FIG. 2 is a diagram showing a parallel connection of a modular computational element according to an embodiment of the present teachings;

FIG. 3 is a diagram showing an in-line connection of a modular computational component according to an embodiment of the present teachings;

FIG. 4 is a block diagram showing an exemplary processor architecture for a modular computational component according to an embodiment of the present teachings;

FIG. 5 is a block diagram showing an exemplary FPGA architecture for an effectively radiation hardened modular computational component according to an embodiment of the present teachings;

FIG. 6 is a block diagram showing an exemplary embodiment of a memory map I/O for an embodiment of a modular computational component in accordance with the present teachings;

FIG. 7 is a block diagram showing an exemplary embodiment of a PCI switch of an embodiment of a modular computational component in accordance with the present teachings;

FIG. 8 is a block diagram showing an embodiment of an inter-PowerPC communication in an embodiment of a modular computational component in accordance with the present teachings;

FIG. 9 is a block diagram showing an exemplary embodiment of a reset architecture for an embodiment of a modular computational element in accordance with the present teachings;

FIG. 10 is a block diagram showing an exemplary embodiment of a power distribution diagram for an embodiment of a modular computational component in accordance with the present teachings; and

FIG. 11 is a diagram showing two sides of an exemplary embodiment of an integrated circuit card incorporating two FPGA devices according to certain embodiments of the present teachings.

### DETAILED DESCRIPTION

In accordance with exemplary embodiments of the present teachings, the modular computational component can include one or more processors, CPUs or other computational engines, one or more memory elements containing instructions to be executed by elements of the computational component, and communication facilities to connect with the platform, with the outside world, and/or with additional modular computational components. A power distribution network may also be included in the modular computational component, for example to route and condition power from the external platform to the modular computational component's various elements.

The modular computational component can be programmed to perform a particular desired function prior to being connected to a receiving device or platform, but preferably is field programmable and reprogrammable. Thus, once connected to the receiving device or platform, the modular computational component can be programmed and/or configured as needed. In some embodiments, changes to the programming and configuration of the modular computational component can be carried out after the receiving device or platform has been deployed.

One exemplary application of the modular computational component according to the present teachings is in remote platforms carrying science instruments that are capable of acquiring large quantities of data, which then has to be transmitted to a distant station or stored (and perhaps processed) on board. An example of this arrangement is found in a space probe sending data back to Earth. The data transmission step may be difficult or expensive in terms of power required, available bandwidth, usable connection time, or other parameters. Data storage can be limited by the available memory. The sensors used in a space-based platform can include, for example, synthetic aperture radar, hyper-spectral instruments, and other instruments to monitor weather, environmental trends, global warming and other parameters.

Because science instruments have high processing requirements and may not be as critical as, for example, safety systems, it can be desirable to give up some reliability for increased processing power. Thus, it may be desirable to employ commercially-available processors that are not fully radiation hardened (but that are radiation tolerant) to realize increased processing power, even if some non-destructive error such as bit flips may occur and need to be mitigated. The present teachings employ radiation hardening by software and/or by design to increase the reliability of such powerful commercially-available radiation tolerant processors.

In certain devices or platforms utilizing a modular computational component in accordance with the present teachings, transmitting or storing all of the data generated by the sensors on the device or platform may not be practical, and an arrangement where some or most of the data processing is carried out before transmission or storage may be advantageous to reduce the amount of data that will need to be transmitted or stored.

For example, synthetic aperture radar (SAR) instruments, for example for planetary and lunar science missions, contemplated for use with a modular computation component in accordance with the present teachings, generate a large amount of raw data that is typically stored on-board and then sent to the ground for processing into images and related products. The SAR data processing algorithms combine/integrate the raw data such that the final SAR data product is typically about ten times to fifty times smaller than the raw data volume. By implementing the traditional SAR data processing functions on-board a spacecraft equipped the a modular computational component in accordance with the present teachings, only the final data products of SAR would need to be stored/downlinked, enabling the instrument to collect, for example, about ten to fifty times more data without increasing onboard storage or communication requirements.

As another example, hyper-spectral instruments, contemplated for use with a modular computation component in accordance with the present teachings, also generate a large amount of raw data that is typically stored on-board and then sent to the ground for processing into images and related products. Ground-based hyper-spectral data processing algorithms often process only select bands, or combine/integrate the raw data such that the final data product volume is typically about ten times to one hundred times smaller than the raw data volume. Current hyper-spectral instruments are capable of producing terabytes of data each day. By implementing the traditional hyper-spectral data processing functions on-board a spacecraft equipped the a modular computational component in accordance with the present teachings, only the final data products of SAR would need to be stored/downlinked, enabling the instrument to collect, for example, about ten to on hundred times more data without increasing onboard storage or communication requirements.

Although the below embodiments of the present teachings are described primarily in terms of sensors used in space exploration probes, other applications that can benefit from the present teachings can be envisioned by those skilled in the art and are contemplated by the present teachings. For example, deep sea probes, platforms used in nuclear reactors, and sensor platforms used in other natural and man-made hostile environments present many of the same challenges as instruments used in space probes, and can benefit from the solutions provided by the present teachings.

Computational components having a modular architecture can be particularly useful as envisioned in the present teachings, because they can be added to a variety of devices or platforms without being custom-designed. Thus, the modular computational components may be used as “off the shelf” units that can be easily added to an instrument platform, communication unit, navigation unit, or other device or platform requiring computing power. In certain embodiments, addition of the modular computational component can be done simply by providing the appropriate data and power connections and by programming/configuring the modular computational component as required. If a greater amount of computing power is desired, more than one of the modular computational components can be connected to the device or platform. In various embodiments of the present teachings, it is possible to retrofit one

According to exemplary embodiments of the present teachings, the modular computational component is able to mitigate errors due to radiation damage. The modular computational component can be connected to an external platform, such as a space probe with sensors that is placed in a radioactive environment that could otherwise cause errors in the data storage and processing. Radiation hardening of the modular computational component can ensure that data processing carried out by the modular computational component is lossless, in that erroneous processed data is not generated and that desired information in the original data can be retrieved after processing.

Radiation hardening according to various embodiments of the present teachings can be achieved in two steps. In one step, radiation tolerant field-programmable gate arrays are utilized to provide radiation hardening by design of the programmable logic in the modular computational element. In a second step, radiation hardening by software is provided to correct or prevent any data errors that may still exist despite the use of radiation tolerant field-programmable gate arrays. Various methods, described in greater detail below, are envisioned by the present teachings to mitigate errors while limiting the computational overhead required for such mitigation.

When a modular computational component in accordance with the present teachings is used in a space probe, it can have sufficient processing power to process data before the data is stored or transmitted to Earth, and can select what data to transmit, prioritize, compress and otherwise manipulate the data at the sensor platform before the data is transmitted or is stored on board. Due to their modular design, one or more computational components can be added to the space probe without the need to design platform-specific components, avoiding the associated expense and time necessary to ensure that the components are sufficiently radiation-hardened.

A number of modular computational components can be added, as necessary, to obtain a desired computational performance, sufficient for example to process large quantities of data produced by the probe's sensors. The on-board lossless data reduction that can be provided by the modular computational component can bring about the migration of typical ground-based processing functions to the probe's sensor platform, resulting in a significant reduction in on-board data storage and downlink requirements.

To achieve these and other benefits, embodiments of the modular computational component have the ability to be “reconfigured on the fly”, meaning that at least some of the modular computational component's software applications, logic structure, and other aspects of the configuration can be modified after manufacture to define how the processor will work. For example, various embodiments of the modular computational component can include a field-programmable gate array (FPGA) and one or more embedded microprocessors and digital signal processing components.

Conventional methods of radiation mitigation include using multiple processors to conduct computations simultaneously, and a comparator or arbiter circuit to compare the results. Generally, at least three processors are needed in a conventional device to identify an erroneous result in one processor that may be caused by radiation. These detection/correction strategies can require large overhead computational costs, often about 50% or more of the total available computational power, which limits the available processing power to process data, operate the platform, or perform other processes. Providing three or more processors that simultaneously carry out the same computations increases the cost and weight of the devices, and wastes a considerable amount of resources.

Various embodiments of a modular computational component according to the present teachings can reduce the computational overhead and wasted computing power of conventional technologies, and can also reduce testing costs and times, since it can be used in multiple different platforms without additional testing or development. By including radiation hardening by design in the modular computational component, radiation testing can be significantly reduced. Because commercially-available radiation hardened and radiation tolerant electronic parts can be used in a modular computational component and are monitored for errors by design and by software, newer processors, memories, and other components can be incorporated as they become available, without the need to extensively test the updated modular computational component to verify the component's resistance to radiation damage.

As described above, the present teachings provide effective radiation hardening of the modular computational component in two steps. In a first step, a radiation tolerant field-programmable FPGA is used, such as, for example, a Virtex-5 FPGA manufactured by Xilinx®, which is capable of eliminating about 95% of the radiation mitigation issues that can affect conventional systems, particularly single-event. However, in the case of a FPGA containing embedded processors such as, for example, PowerPC processors, radiation-induced upsets may still affect the embedded processors and associated memory, and cause single-event upsets such as bit-flips. Critical upsets, however, can be substantially prevented by using a radiation tolerant FPGAs and logic.

The second radiation hardening step of the present teachings, primarily protects the embedded processors used with the FPGA. This second step can include radiation hardening by software to mitigate the effects of possible single-event upsets (e.g., bit flips) caused by radiation. In one example, radiation hardening by software includes providing data corruption indicia to identify incorrect results of computations carried out, for example, in the embedded processors, and causing the computations to be repeated when necessary due to incorrect results.

As will be understood by those skilled in the art, the data corruption indicia can include a scrubber function, a checksum function, error detection and correction (EDAC), or other known methodologies to rapidly determine whether two computations give identical results. For example, a dedicated memory of the modular computational component may be used to store programming instructions that, when executed by a processor, result in at least a part of the radiation hardening by software procedure. Alternatively, programming instructions may be provided when reconfiguring the device. The programming instructions can be stored at least in part in other memory components of the modular computational component according to embodiments of the present teachings.

Verifying data corruption indicia utilizing certain embodiments of the present teachings can require only two processors to carry out identical computations and verify the results. This compares well with the at least three processors necessary in a conventional redundant apparatus with an arbiter circuit. Instead of executing three identical computations and discarding the one that gives a different result, the present teachings envision comparing the checksums (or other data corruption indicia) of two identical computations, and repeating the computation if the checksums are different. In an exemplary scheme, the modular computational component comprises two PowerPCs that can perform the same calculations, and the resulting checksum values can be compared to verify the accuracy of the calculations.

Compared to a present state of the art radiation hardened processor, such as the BAE Systems RAD750, embodiments of the modular computational component according to the present teachings can provide up to approximately 100 times the processing power, and mitigation of radiation errors that are essentially as effective as that of the state of the art. This is obtained at a fraction of the cost and time involved in developing a radiation hardened processor dedicated to a specific application.

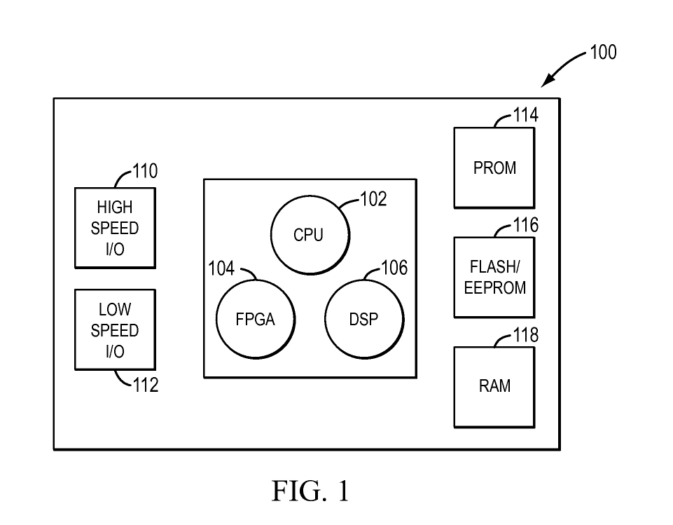

FIG. 1 shows an exemplary embodiment of a modular computational component 100 according to the present teachings. The exemplary modular computation component 100 includes a CPU 102, an FPGA 104 and digital signal processing (DSP) element 106. In certain embodiments, the CPU 102 can comprise one or more PowerPC processors, or alternatively can comprise a LEON processor designed by the European Space Agency, a Freescale ColdFire microprocessor, an ACTEL processor or any other processor that is suitable for embedding in a computational device.

In various embodiments, the FPGA 104 can include a Virtex-5 processor manufactured by Xilinx®, or another suitable FPGA. According to the present teachings, the FPGA is radiation tolerant to prevent or mitigate errors and data loss in radioactive environments. In certain embodiments, the FPGA 104 can include two or more devices, which can be mounted for example in a back-to-back or in a nearly end-to-end configuration to minimize the space and volume of the installation and obtain computational efficiencies. Nearly end-to-end, as used herein, includes a nearly or partially back-to-back configuration having a certain degree of area overlap between the two devices. Those of skill in the art will understand that configurable architectures other than FPGAs can be used in accordance with the present teachings, such as software-configurable microprocessors and other reconfigurable systems.

The exemplary modular computational component 100 can also include a digital signal processor (DSP) 106, adapted to carry out digital processing of signals. For example, the signals can include data generated by a sensor platform, which data can be processed or otherwise manipulated before being stored in memory and/or transmitted to a distant station. The DSP 106 can, for example, carry out analysis, compression, selection, or other processes that can be adapted to reduce the amount of information stored or transmitted over a data link. Additional functions can be carried out by the DSP 106, as directed by the FPGA or by instructions from outside the device.

A high speed I/O connection 110 and a low speed I/O connection 112 can be provided in an embodiment of the modular computational component 100, to integrate the modular computational component 100 with the data flow of the platform. For example, the I/O connections 110, 112 can support a variety of formats and specifications adapted to the specific mission of the device. These can include serial, parallel, USB, Ethernet, Firewire, Spacewire, LVDS, Rocket I/O, and/or other custom and standard interfaces. A PROM 114 can be provided in the exemplary modular computational component 100 for CPU boot, health and safety, and basic command and telemetry functions. RAM memory 118 can be included for program execution. Flash/EEPROM memory 116 can be used to store algorithms, instructions, and application code for the CPU 102, FPGA 104, and DSP 106. Instructions to carry out the radiation hardening by software can be stored in one or more of the above memories. Those of skill in the art will understand that other components and different configurations may be used to achieve the ability to reconfigure the device, and to update, modify, and/or replace algorithms at any point during a mission.

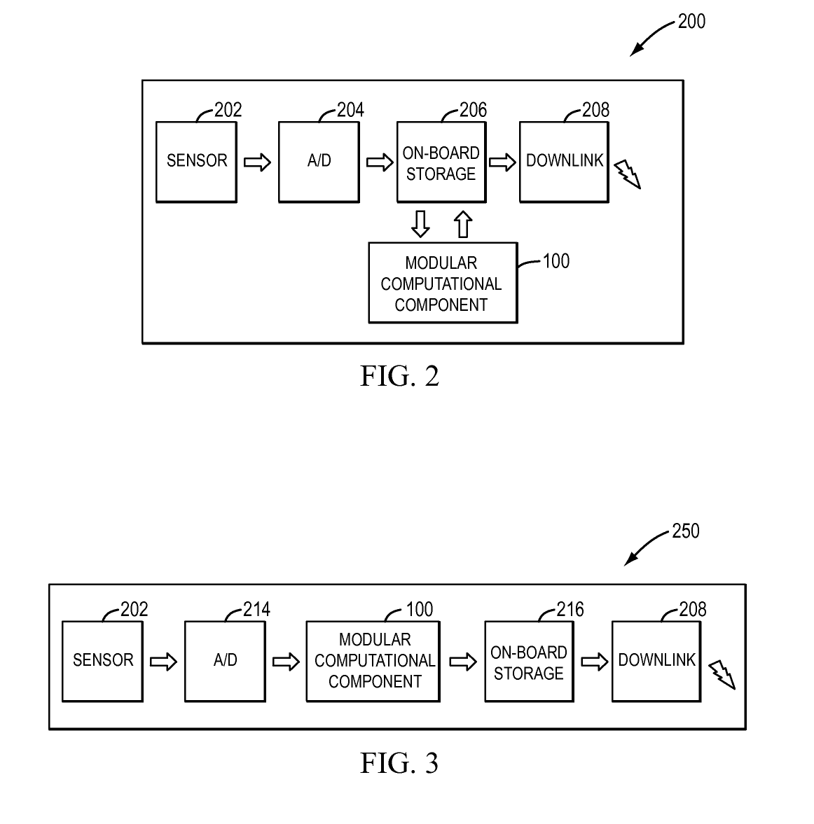

FIGS. 2 and 3 show exemplary system configurations for integrating a modular computational component 100 according to the present teachings into the data flow of an external instrumentation platform. In a first configuration shown in FIG. 2, a parallel on-board data processor 200 utilizes a modular computational component 100 in parallel with the data stream through an on-board storage element 206, for example, of a space probe. In this configuration, one or more sensors 202 generate data, which goes through an Analog/Digital converter 204 before reaching on-board storage 206. The modular computational component 100 is not directly in the data collection stream, but is connected to the on-board storage device 206 from which it can read raw data, execute desired algorithms, and generate desired products that can be stored back in the on-board storage 206. The processed data can then be retained in memory and/or transmitted via a downlink 208.

In the configuration illustrated in FIG. 2, processing can occur in near real-time, and upsets such as bit flip errors can be corrected by simply re-executing a processing step when an error is detected, for example by recognizing data corruption indicia, thus obtaining “perfect data” at the output. This configuration is well suited for use as a retrofit on existing sensor platforms, or on systems where data collection periods are followed at least by a minimal amount of idle time.

In a second system configuration for integrating a modular computational component 100, as shown in FIG. 3, the modular computational component 100 is connected in-line within the on-board data processor 250. Here, the modular computational component 100 is directly in the data stream of the device, for example located between the analog to digital converter (A/D) 214 and the on-board storage 216. This configuration may be better suited for instrument platform systems having strict real-time requirements for data processing, and/or extremely high data rates, where the volume of data has to be reduced prior to storage in the on-board storage 216.

The in-line configuration illustrated in FIG. 3 is capable of processing very high data rates, however may be subject to occasional errors, such as bit-flip errors or “bad pixel” errors due to radiation, if the data rate exceeds the recovery time for re-executing a processing step that is determined to be in error. In cases where the data rate is not extreme, and/or when there are some idle periods in the data collection stream, this configuration is also able to produce data with substantially no errors, by re-executing erroneous steps during the slower or idle periods.

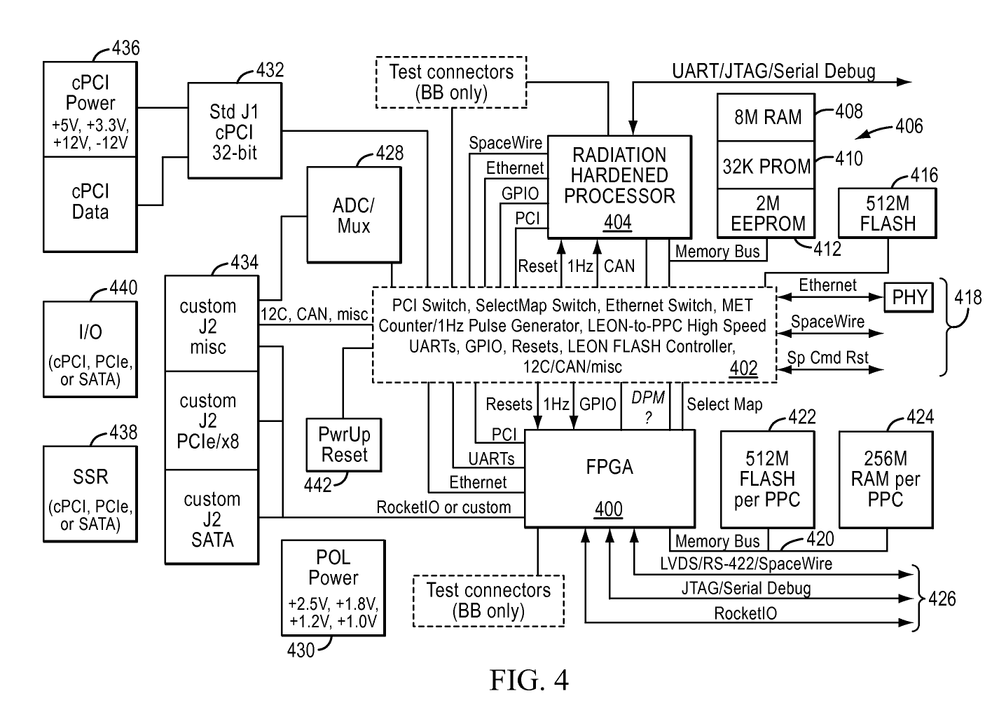

FIGS. 4-10 depict schematic block diagrams of an exemplary modular computational component according to an embodiment of the present teachings, in

FIG. 4 depicts an exemplary processor architecture of a modular computational component 100 according to the present teachings. In this embodiment, an FPGA 400, such as a Xilinx® Virtex-5, is connected to one or more interconnects 402 that can, for example, include one or more PCI switch, Select Map switch, Ethernet switch, MET counter/1 Hz generator, LEON-to-PPC High-Speed universal asynchronous receiver/transmitter (UART), GPIO, Resets, LEON flash controller, I2C, Controller Area Network, and/or other miscellaneous interconnects. The interconnects 402 can form an interface via multiple connectors 418, including, for example, Ethernet, SpaceWire, a connection for a “special command reset” and other custom or standard interfaces and physical interfaces (PHY). The interconnects 402 can be considered the logical “glue” that connects the various components of the reconfigurable system. A memory bus 406 can be connected to the interconnects 402, and can comprise, for example, RAM 408, PROM 410, EEPROM 412 and Flash memory components 416, as needed to operate and reconfigure the modular computational component 100. Another memory bus 420 can be connected to the FPGA 400 and, for example, can comprise RAM 424 and Flash memory 422 for each of the processors embedded in the device.

In accordance with various embodiments of the present teachings, one or more of the above-described memories can be used to store the data and instructions necessary to carry out radiation hardening by software according to the present teachings. In an exemplary embodiment, the necessary scrubber functions and data corruption indicia are executed, for example as background processes, for the processors, the FPGA, and the other elements of the modular computational component. It can therefore be beneficial to store at least a portion of the radiation hardening instructions in the memories associated with the devices for which scrubber functions and data corruption indicia are to be executable.

An additional microprocessor 404 can be embedded in the modular computational component. The microprocessor can comprise, for example, a radiation hardened LEON 3 processor 404, which can be connected to the reconfigurable logic of the interconnects 402. The additional processor 404 in this exemplary embodiment can be used to control an interface with the external platform, such as a spacecraft's data system. The additional processor 404 can thus operate as an external platform processor, to handle tasks for the external platform outside of the sensor data processing. The exemplary connections of the LEON 3 processor 404 and other connections to/from the interconnects 402 can include SpaceWire, Ethernet, PCI, GPIO, UART, RocketIO and other standardized or custom connections. At least some of these connections can form an I/O portion of the modular computational component, so that the modular computational component can be connected to data connections of the external platform. The additional microprocessor 404 preferably comprises a microprocessor that is radiation hardened by process, and therefore experiences neither recoverable nor destructive errors when utilized in a hostile environment. The additional microprocessor 404 therefore may be less powerful than the FPGAs 400 of the modular computational component. However, because the additional microprocessor 404 experiences neither recoverable nor destructive errors when utilized in a hostile environment, the additional microprocessor 404 can serve as a watchdog, control the FPGAs 400, and check output from the FPGAs for errors (in addition to the FPGAs checking themselves for errors as set forth above).

In accordance with certain embodiments of the present teachings, an analog/digital converter and multiplexer 428 can be also provided, and can be connected to multiple custom J2 connectors 434 for further connection with various I/O devices 440 and SSR devices 438.

The interconnects 402 can also include standard J1 connectors 432 for power and data channels 436 of one or more card slots such as, for example, Compact PCI (cPCI) card slots. A power source with voltage regulation 430 can be used to provide power to the exemplary modular computational component 100, and may be connected, for example, to the power distribution system of the external platform (not shown). A reset logic 442 can provide a control signal to the interconnects 402.

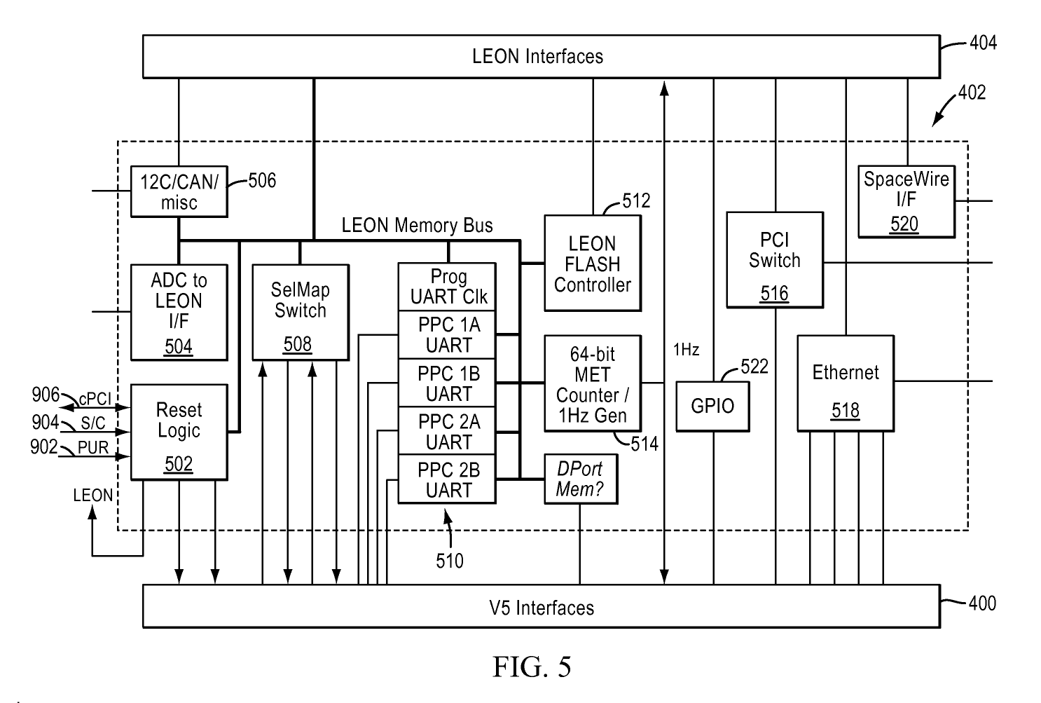

FIG. 5 shows a more detailed view of the interconnects 402 shown in FIG. 4. In the configuration shown in FIG. 5, the interconnects 402 are adapted to form a programmable logical architecture disposed between the interfaces to the radiation hardened processor 404 and the FPGA 400.

The interconnects 402 can include a reset logic 502 which manages inputs from internal/external hardware through, for example, a Compact PCI 906, a special command (S/C) software reset 904, and a power up reset (PUR) 902. The reset logic 502 can output a signal to the various components when a reset is necessary, for example, as part of the radiation hardening by software procedure.

The embodiment illustrated in FIG. 5 also comprises an ADC to LEON connection 504, which can be used to provide data regarding local on-board and off-board temperatures, voltages, and currents, for example, via a J2 connector (not shown). An I2C/CAN/Miscellaneous connection 506 can provide a simple pass through, an I2C core, or a miscellaneous I/F via a J2 connector, providing a housekeeping interface used for miscellaneous low-rate date sharing. A plurality of high speed UARTs 510 can be used for each of the PowerPCs and for the clock. The UARTs 510 can provide general internal data transfer paths from the additional processor 404 to one or more PowerPCs. Although PowerPCs are described for use in this exemplary implementation and those set forth below, one skilled in the art will appreciate that other suitable processors may alternatively be employed.

The exemplary embodiment illustrated in FIG. 5 can also include a flash controller 512, such as a LEON flash controller, to manage interactions with a flash memory bank (not shown), LEON flash memory bank. A 64-bit MET Counter/1 Hz generator 514 can be employed to maintain time and distribute synchronization signals. A general purpose I/O (GPIO) 522 can be used for the additional processor

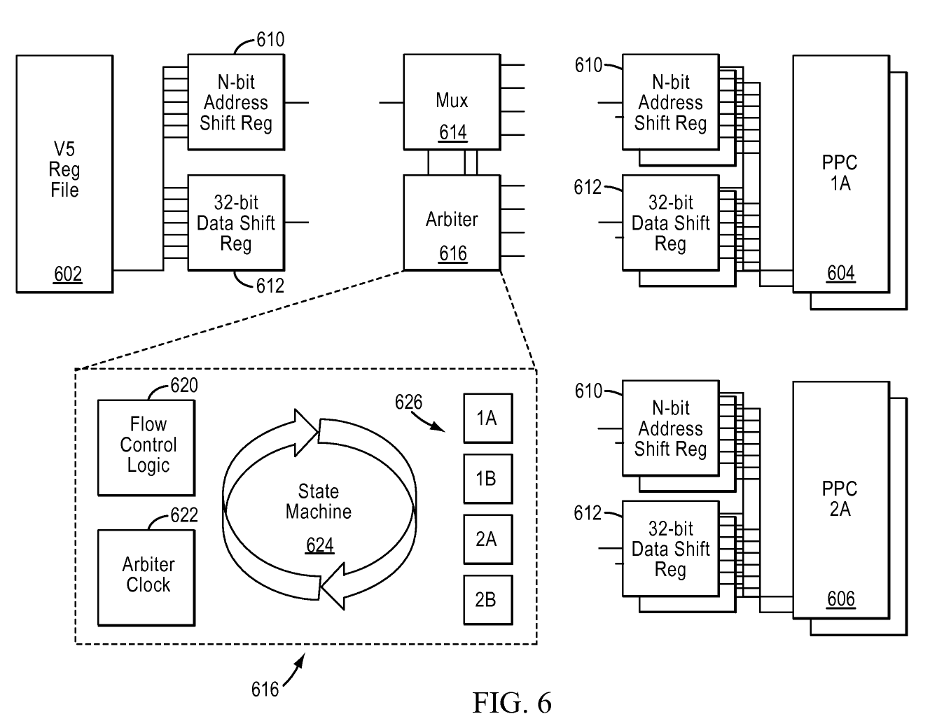

An exemplary embodiment of a memory map I/O according to the present teachings is shown in the block diagram of FIG. 6. The FPGA 400 includes a registry file 602 that is shown schematically connectable to a pair of PowerPCs 604, 606. For example, each modular computational component according to the present teachings can include two FPGAs, having a total of four PowerPCs. Each FPGA-to-PowerPC connection can include a N-bit Address Shift register 610 and a 32-bit Data Shift Register 612. In the exemplary illustrated embodiment, a multiplexer 614 and an arbiter 616 are disposed between the FPGA and the two connected PowerPCs 604, 606. A greater detail of the exemplary arbiter 616 is also shown. The arbiter 616 can include a state machine 624 operating on flow control logic 620 and an arbiter clock 622 on one side. The arbiter 616 can be used to provide the processors with access to shared memory.

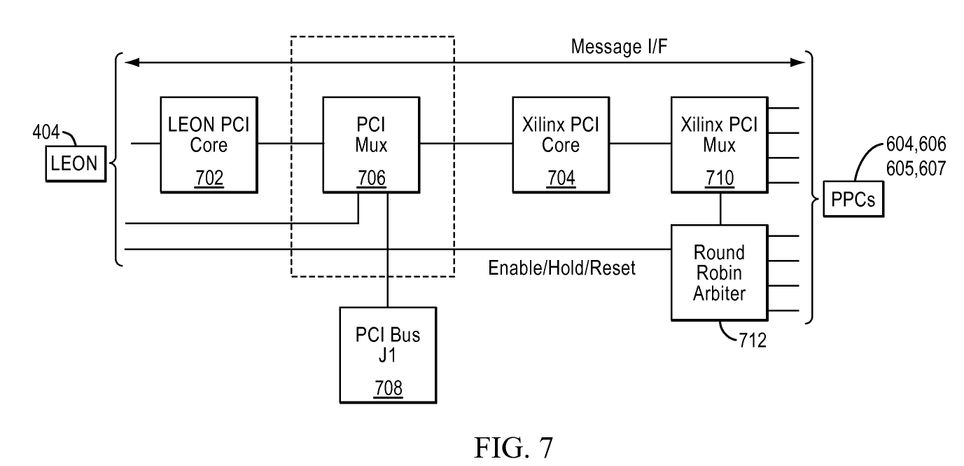

FIG. 7 shows an exemplary PCI switch diagram for use in accordance with the present teachings. For example, the illustrated PCI switch can connect the additional processor 404 to the PowerPCs 604-607 discussed above. The PCI switch can include a PCI multiplexer 706 disposed between a PCI core 702 for the additional processor 404, and a PCI core 704 for the FPGA 400. A PCI J1 bus 708 can be connected to the multiplexer 706. The PCI core 704 can be further connected to a PCI multiplexer 710 for a Xilinx® Virtex-5 FPGA and a round robin arbiter 712, which in turn are connected to the PowerPC's.

According to this exemplary configuration, the LEON PCI core 702 acts as a PCI bus master and default PCI bus controller. In operation, one of the PowerPCs 604-607 requests PCI access from the round robin arbiter 712, which grants access to the requesting PowerPC. The PowerPC may also request access to the PCI bus 708 via a message to the LEON core 702. The LEON core 702 can then configure the PCI bus switch to pass the PowerPC data, and the LEON core 702 can grant PCI bus access to the PowerPC and send, for example, a “PCI GO” message. The PowerPC can serve as the PCI bus master and transfer the data, and when that is completed, the PowerPC can send a “PCI DONE” message to the LEON core 702 and remove the request from the round robin arbiter 712. The LEON core 702 can monitor the PPC/PCI transfer time-out, and resume control of the PCI Bus 708 after the “PCI DONE” message is received or after a time-out.

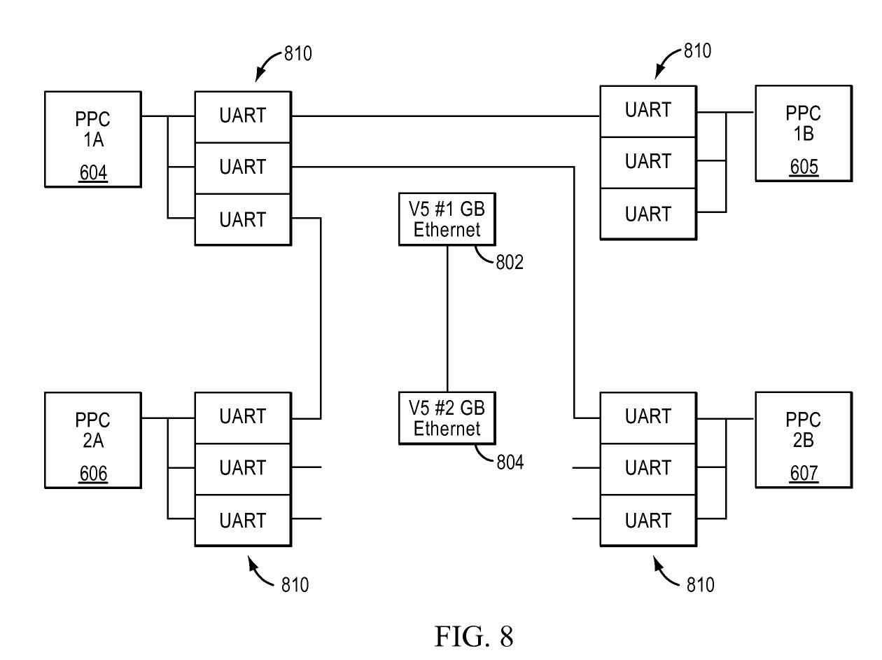

An exemplary embodiment of an inter-PowerPC communication schematic is shown in FIG. 8. In this embodiment, four PowerPCs 604-607 are connected to each other by a series of universal asynchronous receiver/transmitters (UARTs) 810. Those of skill in the art will understand that more or fewer UARTs can be used, depending on the communication demands of the sensor platform or other device using the modular computational component according to the present teachings. The inter-PowerPC communication scheme may alternatively or additionally utilize Ethernet ports 802, 804 of the FPGAs.

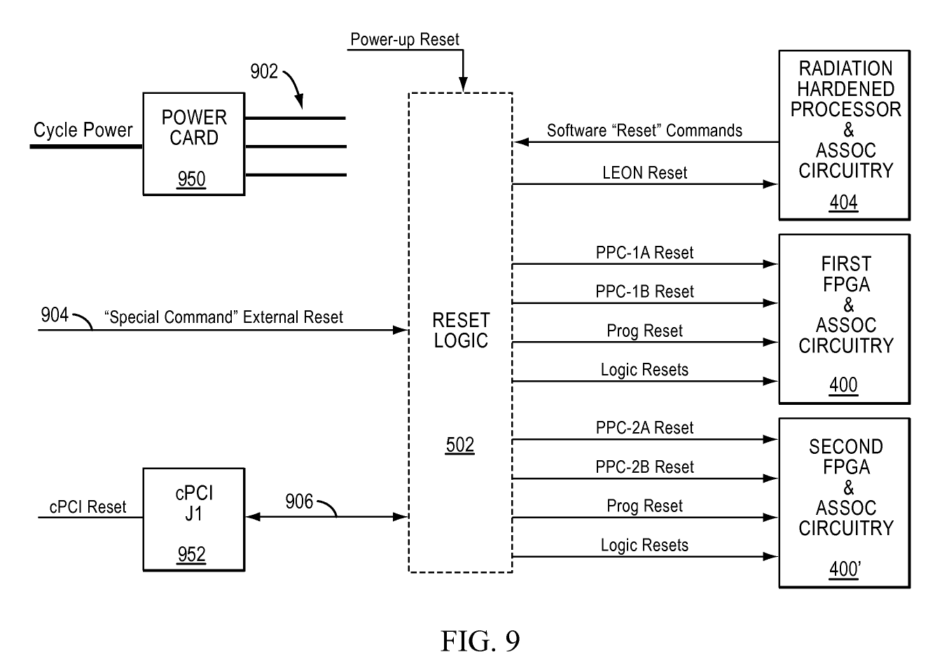

An exemplary reset architecture of the modular computational component according to an embodiment of the present teachings is shown in FIG. 9. When a serious fault due to radiation is discovered, the reset architecture can provide one or more paths to correct the fault.

The exemplary reset logic element 502 of FIG. 9 provides a more detailed view of the reset logic 502 shown in FIG. 5. The reset logic element 502 can be connected to the interfaces of the additional processor 404 and to the interfaces of the FPGAs 400, 400′. The reset signals sent to the FPGAs 400, 400′ and the additional processor 404 can include, for example, software reset commands, LEON reset commands, PowerPC resets, logic resets, and program resets. The inputs to the reset logic 502 can include, for example, special command (SC) external resets 904, power card resets 902, and compact PCI resets 906. These reset commands can originate, for example, from the radiation hardening software, from a command received from Earth (in the case of a space probe), or from hardware of the external platform when a fault is discovered.

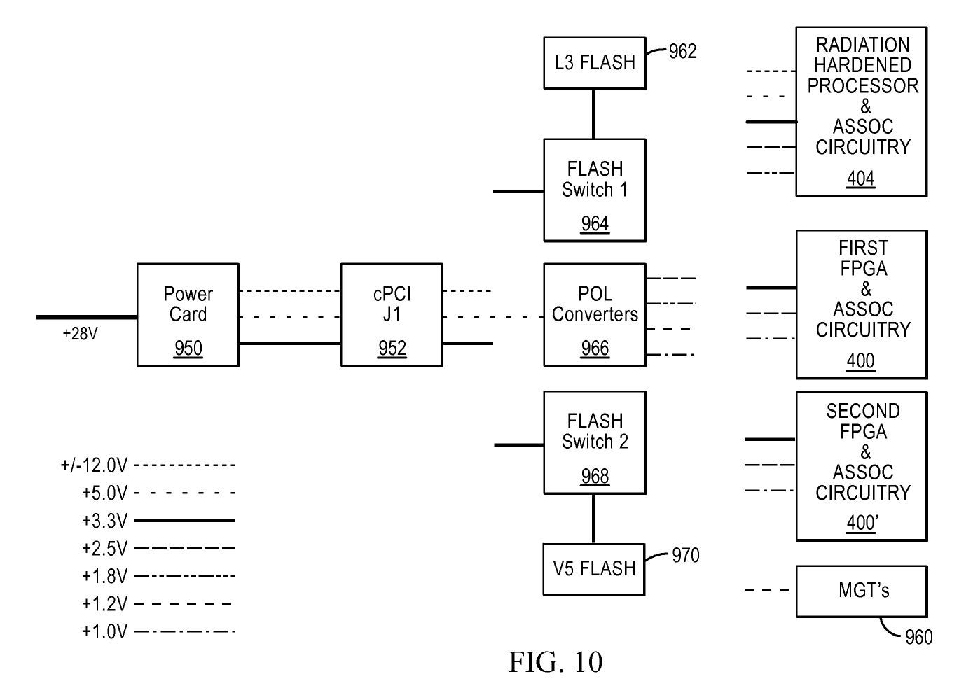

An exemplary power distribution scheme for a modular computational component according to the present teachings is shown in FIG. 10. A power card 950 can provide power via a J1 connector of a compact PCI 952, which can itself receive power, for example, from a power supply from a spacecraft or other external platform. From there, power from an exemplary +28V source can be distributed as needed, for example through consumer circuits providing +5V, +3.3V, +2.5V, +1.8V, +1.2V and +1.0V to the specific circuits, as needed. These consumer circuits can include, for example, an L3 flash 962, a Flash Switch 1 964, one or more POL Converters 966, a Flash Switch 2 968, and a Virtex-5 flash 970. In addition, power can be provided to the consumer circuits for the additional processor 404 and its associated circuitry, one or more FPGAs 400, 400′ and their associated circuitry, and one or more multi-gigabit transmitters (MGTs) 960. MGTs are super high speed serial data lines that can be used to transmit data very quickly, for example from an instrument to a processor or to on-board storage. Those of skill in the art will understand that different voltage distribution schemes can also be used, within the scope of the present teachings.

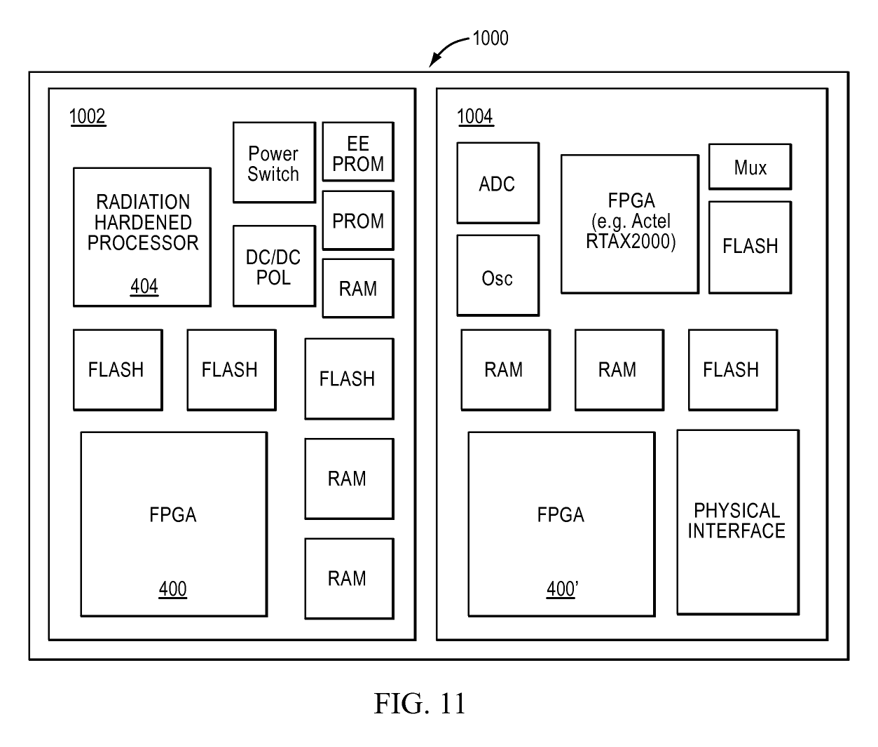

FIG. 11 shows an exemplary physical configuration of an integrated circuit card 1000 in accordance with the present teachings. Two faces 1002, 1004 of the card 1000 are shown, in which a pair of processors, such as FPGAs 400, 400′ as mentioned above, are mounted on the same integrated circuit card 1000 to limit the space taken up by the processors 400, 400′. In this example, the modular computational component incorporates two Xilinx® Virtex-5 FPGAs 400, 400′, which are mounted in a nearly end-to-end configuration and adapted to maximize data transfer and computing performance while retaining simple manufacturing of the integrated circuit card. It will be understood by those skilled in the art that different processors, memory chips, and FPGAs can be used in a similar configuration in accordance with the present teachings.

To minimize the dimensions of the integrated circuit card 1000 using multiple redundant electronic components, pairs of components can be mounted in a nearly end-to-end configuration, in which the connections of each of the pairs of components are at least partially overlapping. For example, the two FPGA's 400, 400′ can share at least some common vias or other types of interconnects on the circuit board 1000 by virtue of their nearly end-to-end configuration. In certain embodiments of the present teachings, the power supply, the grounding, and some data inputs and outputs can be shared by components mounted in such a nearly end-to-end configuration. In certain embodiments, unique signals intended for only one of the components having shared inputs and outputs facilitated by an overlapping configuration can have dedicated interconnects or vias, for example, located at the outermost connections, to simplify the wiring of the two components.

Both back-to-back and nearly end-to-end configurations for the FPGAs can advantageously allow maximization of connections (by sharing common connections) to the FPGAs to prevent bottlenecks for data going between the FPGAs. However, putting the FPGAs completely back-to-back can cause blind vias during assembly, so that the boards cannot be adequately checked or inspected. In a nearly end-to-end configuration with, for example, an overlap of about one third to two thirds of the area of the FPGAs, manufacturing problems such as blind vias can be avoided while bottlenecking can still be prevented because a sufficient amount of common connection sharing can take place.

In accordance with the present teachings, by properly grouping common inputs and outputs to and from components having a nearly end-to-end configuration, it is possible to execute the same instructions or code on both of the components sharing the nearly end-to-end configuration. This is useful in the context of radiation hardening by software, according to embodiments of the present teachings, where the same code, instructions or application is run on two identical components (i.e., the two FPGAs) and the resulting data corruption indicia are compared to identify errors and repeat the computations. This integrated circuit card configuration permits very high component densities and can result in the smallest amount of physical space required for the components comprising the integrated circuit card 1000.

The present teachings have been described with reference to specific exemplary embodiments. Other embodiments of the present teachings will be apparent to those skilled in the art from consideration of the specification and practice of the teachings disclosed herein. It is intended that the specification and examples be considered as exemplary only, with a true scope and spirit of the teachings being indicated by the following claims.

What is claimed is:

1. A modular computational component connectable to an external platform, the modular computational component comprising:
an input/output portion having at least one connection for receiving an input signal to be processed, and at least one connection for sending a processed output signal to the external platform;
a radiation tolerant first field programmable gate array having a pair of processors configured to process the input signal;
a first memory configured to contain reconfigurable instructions for the pair of processors that, when the reconfigurable instructions are executed, process the input signal and obtain the output signal;
a second memory containing instructions that, when executed, provide radiation hardening by software for at least the pair of processors, by identifying radiation-induced errors and taking corrective action; and
a reset logic element configured to selectively reset at least one of the first field programmable gate array and at least one of the pair of processors in response to a reset command.

2. The modular computational component according to claim 1, wherein the first memory contains instructions that are reconfigurable after connection of the modular computational component to the external platform.

3. The modular computational component according to claim 1, wherein the second memory contains instructions to perform identical processing operations in each of the pair of processors, compare data corruption indicia for the identical processing operations, and repeating the identical processing operations if the data corruption indicia disagree.

4. The modular computational component according to claim 3, wherein the data corruption indicia comprise a checksum function.

5. The modular computational component according to claim 1, wherein the second memory comprises instructions to execute a scrubber function.

6. The modular computational component according to claim 5, wherein the scrubber function checks data from at least one of the pair of processors and the first field programmable gate array.

7. The modular computational component according to claim 1, further comprising an external platform processor connected to the first field programmable gate array.

8. The modular computational component according to claim 7, wherein the first field programmable gate array comprises interfaces to the external platform processor and the pair of processors.

9. The modular computational component according to claim 1, wherein the reset logic element comprises logic architecture configured to receive reset signals from at least one of a power manager, external hardware, internal hardware, and a software reset.

10. The modular computational component according to claim 9, wherein the logic architecture receives the reset signals in response to an error detected in one of the first field programmable gate array, the pair of processors, and an external platform processor.

11. The modular computational component according to claim 9, wherein the reset signals from the external platform processor received by the logic architecture comprise special commands from a station remote to the external platform.

12. The modular computational component according to claim 5, wherein the scrubber function executes on at least one of the pair of processors, the first field programmable gate array and an external platform processor.

13. The modular computational component according to claim 1, wherein the pair of processors comprise at least two PowerPC processors.

14. The modular computational component according to claim 1, further comprising a second field programmable gate array and second pair of processors, the second field programmable gate array and the second pair of processors being mounted nearly end-to-end with the first field programmable circuit and partially overlapping the first field programmable gate array.

15. The modular computational component according to claim 14, wherein the nearly end-to-end mounting is configured to facilitate sharing of common signals between the first and second field programmable gate arrays.

16. A method of providing radiation hardening for a modular computational component having a first memory and a second memory and being connectable to an external platform, the method comprising:
providing a radiation tolerant field programmable gate array having a pair of processors;
processing data from the external platform according to instructions stored in the first memory; and
executing instructions stored in the second memory to provide radiation hardening by software, the instructions comprising instructions to execute identical processing operations for the data of the external platform in each of the pair of processors, instructions to identify a data corruption indicia for each of the identical processing operations, instructions to compare the identified data corruption indicia, and instructions to repeat the identical processing operations if the data corruption indicia show corrupted data.

17. The method according to claim 16, further comprising issuing a reset command when the data corruption indicia show corrupted data.

18. The method according to claim 17, wherein issuing the reset command comprises issuing a reset signal to reset at least one of the field programmable gate array and the pair of processors.

19. The method according to claim 18, further comprising issuing the reset signal in response to a fault command from one of the field programmable gate array, the pair of processors, an external platform processor, and a software command.

20. A modular computational component connectable to an external platform, the modular computational component comprising:
an input/output portion having at least one connection for receiving an input signal to be processed, and at least one connection for sending a processed output signal to the external platform;
a radiation tolerant field programmable gate array having a pair of processors configured to process the input signal;
a first memory configured to contain reconfigurable instructions for the pair of processors that, when the reconfigurable instructions are executed, process the input signal and obtain the output signal;
a second memory containing instructions that, when executed, provide radiation hardening by software for at least the pair of processors, by identifying radiation-induced errors and taking corrective action;
a radiation hardened microprocessor configured to check output from the field programmable gate array for radiation-induced errors and take corrective action; and
a reset logic element configured to selectively reset at least one of the first field programmable gate array and at least one of the pair of processors in response to a reset command.
